(19) United States
(12) Patent Application Publication
(10) Pub. No.: US 2015/0077125 A1
(43) Pub. Date: Mar. 19, 2015

(54) SETTING DEVICE, BATTERY ASSEMBLY DEVICE AND SETTING METHOD

(71) Applicant: NEC CORPORATION, Tokyo (JP)

(72) Inventor: Yojiro Nomura, Tokyo (JP)

(21) Appl. No.: 14/386,841

(22) PCT Filed: Feb. 15, 2013
(86) PCT No.: PCT/JP2013/053699

§ 371 Date: Sep. 22, 2014

(30) Foreign Application Priority Data
Mar. 22, 2012 (JP) 2012-065445

(51) Int. Cl. H01M 10/48; H01M 10/44; G01R 31/36

(52) U.S. Cl. CPC H01M 10/482; G01R 31/362; H01M 10/44
USPC 324/427

(57) ABSTRACT

Provided are a setting device, a battery assembly device and a setting method that prevent SOC errors from accumulating. The setting device for determining the SOC of a target storage battery unit for setting among a plurality of storage battery units includes: a state setting means for setting the storage battery unit into one of two predetermined states, either a fully charged state or a fully discharged state; a plurality of first switches, corresponding to the plural storage battery units respectively, and that are each interposed between the corresponding storage battery unit and the state setting means; a plurality of second switches, corresponding to the plural storage battery units respectively, and that are each interposed between the corresponding storage battery unit and the power line; and, a control means that turns on the first switch, among the plural first switches, corresponding to the target storage battery unit to be set into a predetermined state, turns on the second switches among the plural second switches, other than the second switch, corresponding to the target storage battery unit to be set into a predetermined state, and determines the SOC of the target storage battery unit that is to be set to the value corresponding to the predetermined state when the state setting means sets the target storage battery unit that is to be set into the predetermined state.

### TECHNICAL FIELD

The present invention relates to a setting device, a battery assembly device and a setting method, in particular relates to a setting device, a battery assembly device and a setting method for setting the SOC of a storage battery unit to be set among a plurality of storage battery units.

### BACKGROUND ART

There has been known a battery assembly formed of a plurality of connected storage batteries (e.g., a plurality of lithium-ion secondary battery cells).

Patent Document 1 discloses a battery assembly system in which a plurality of series battery units, each having multiple storage batteries connected in series, are connected in parallel. Hereinbelow, the series battery unit may also be called storage battery unit.

The remaining storage capacity of a storage battery unit is generally represented by SOC (State of Charge).

SOC may be calculated from the voltage of the storage battery unit, or may be calculated by addition and subtraction of the charged capacity and discharged capacity of the storage battery unit.

### Related Art Documents

### Patent Documents

Patent Document 1: JP2010-29015A

### SUMMARY OF THE INVENTION

### Problems to be Solved by the Invention

When SOC is calculated from the voltage of the storage battery unit, if a change in the voltage of the storage battery unit is small during discharge, it is difficult to accurately relate the change in voltage to the change in SOC, and thus it becomes difficult to determine the exact SOC.

For this reason, it is preferable to determine SOC by performing addition and subtraction of the charged capacity and discharged capacity of the storage battery unit, instead of calculating SOC from the voltage of the storage battery unit.

When SOC is determined by performing addition and subtraction of the charged capacity and discharged capacity of the storage battery unit, as the initial setting, the SOC needs to be set at 100% when the storage battery unit is fully charged and the SOC needs to be set at 0% when the storage battery unit is completely discharged, then the SOC is calculated by performing addition and subtraction of the charged capacity and discharged capacity of the storage battery unit.

However, errors often arise when SOC is estimated from the charged capacity and discharged capacity. As a result, when storage battery units are used in a power system in which the storage battery units are repeatedly charged and discharged without having been fully charged or fully discharged, a problem will occur in which SOC errors accumulate.

The object of the present invention is to provide a setting device, a battery assembly device and a setting method that can resolve the above problem.

### Means for Solving the Problems

The setting device of the present invention is a setting device for determining the SOC of a target storage battery unit for setting among a plurality of storage battery units for which charging and discharging is performed using a power line, and comprises: a state setting means that sets the storage battery unit into one of two predetermined states, a the fully charged state or a fully discharged state;

a plurality of first switches, corresponding to the plural storage battery units respectively, and each interposed between the corresponding storage battery unit and the state setting means;

a plurality of second switches, corresponding to the plural storage battery units respectively, and each interposed between the corresponding storage battery unit and the power line; and,

a control means that turns on the first switch, among the plural first switches, corresponding to the target storage battery unit to be set into a predetermined state, turns on the second switches among the plural second switches, other than the second switch, corresponding to the target storage battery unit to be set into a predetermined state, and determines the SOC of the target storage battery unit that is to be set to the value corresponding to the predetermined state when the state setting means sets the target storage battery unit that is to be set into the predetermined state.

The battery assembly device of the present invention includes a plurality of storage battery units and the above setting device.

The setting method of the present invention is a setting method for use in a setting device for determining the SOC of a target storage battery unit for setting among a plurality of storage battery units for which charging and discharging is performed using a power line, the setting device including a state setting means for setting the storage battery unit to one of predetermined states, either the fully charged state or the fully discharged state, and comprises the steps of:

turning on the first switch corresponding to the target storage battery unit for setting among the plural first switches that respectively correspond to the plural storage battery units and that are each interposed between the corresponding storage battery unit and the state setting means;

turning on the second switches other than the second switch corresponding to the target storage battery unit for setting among the plural second switches that respectively correspond to the plural storage battery units and that are each interposed between the corresponding storage battery unit and the power line; and,

determining the SOC of the target storage battery unit for setting to be the value corresponding to the predetermined state when the state setting means sets the target storage battery unit for setting the storage battery unit into the predetermined state.

### Effect of the Invention

According to the present invention, it is possible to prevent SOC errors of storage battery units from accumulating, in a power system in which the storage battery unit is repeatedly charged and discharged without being fully charged or fully discharged.

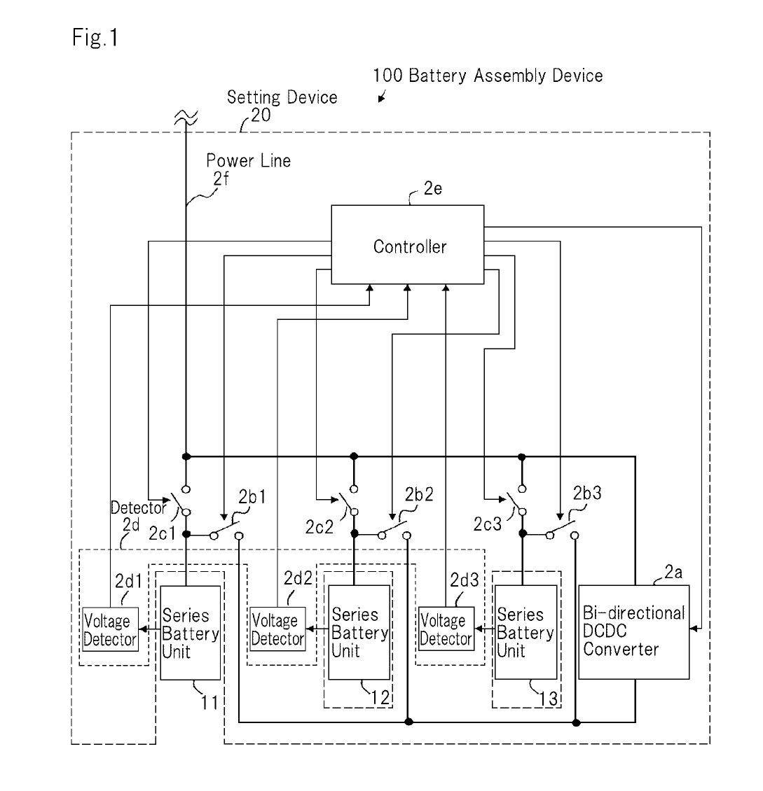

### BRIEF DESCRIPTION OF THE DRAWINGS [FIG. 1]

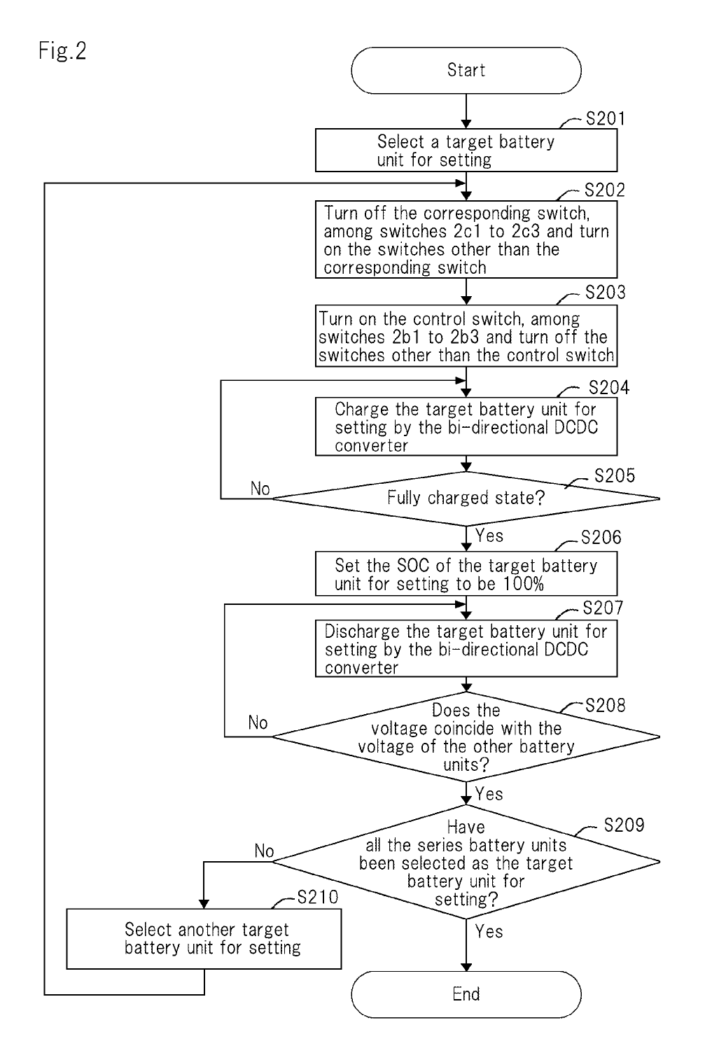

A block diagram showing battery assembly device 100 of one exemplary embodiment of the present invention.

[FIG. 2]

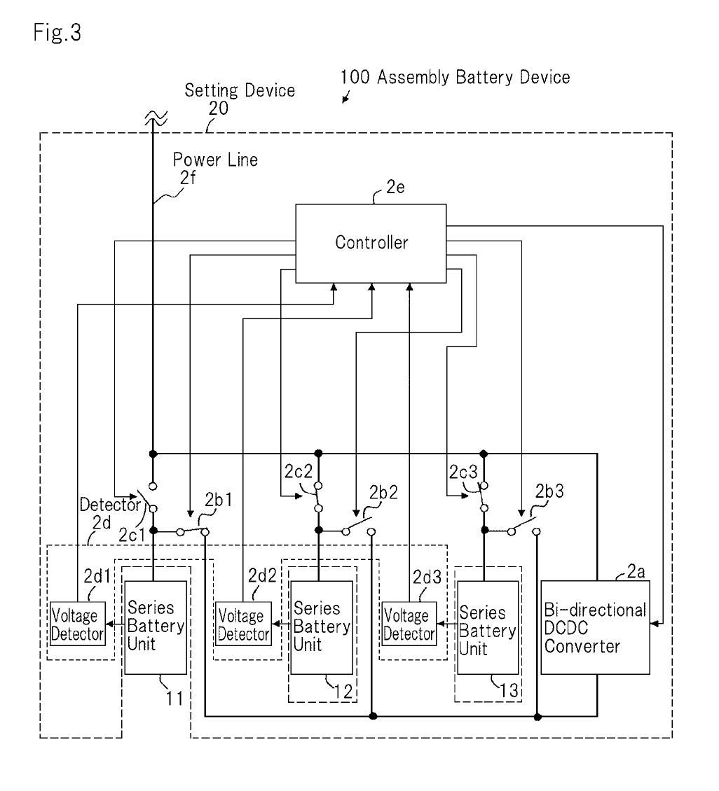

A flow chart for illustrating the operation of setting device 20. [FIG. 3]

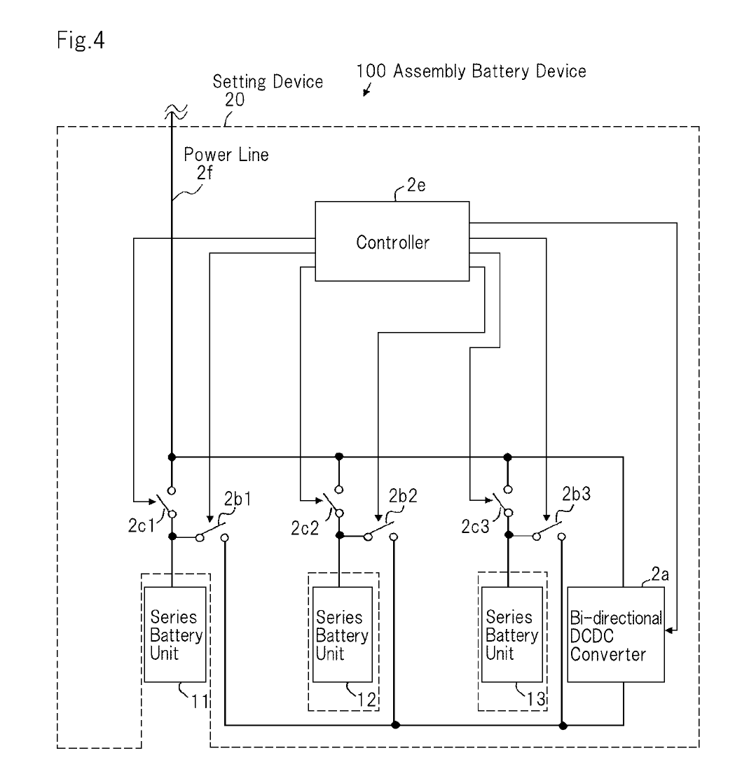

A diagram for illustrating one example of on/off states of switches. [FIG. 4]

A diagram showing setting device 20 formed of bi-directional DCDC converter 2a, switches 2b1 to 2b3 and switches 2c1 to 2c3, and controller 2e.

### MODE FOR CARRYING OUT THE INVENTION

Hereinbelow, one exemplary embodiment of the present invention will be described with reference to the drawings.

FIG. 1 is a block diagram showing battery assembly device 100 of one exemplary embodiment of the present invention.

In FIG. 1, battery assembly device 100 includes series battery units 11 to 13 and setting device 20.

Series battery units 11 to 13 are one example of the plural storage battery units. Series battery units 11 to 13 are connected in parallel to each other. Series battery units 11 to 13 each have a plurality of storage batteries (e.g., plural lithium-ion secondary battery cells) connected in series.

Here, the storage battery is not limited to a lithium-ion secondary battery cell, but may be changed as appropriate. As the storage battery unit, a single secondary battery cell may be used instead of the series battery unit. Further, in FIG. 1, the number of series battery units is 3, but the number of series battery units may be 2 or more.

Setting device 20 includes bi-directional DCDC converter 2a, switches 2b1 to 2b3, switches 2c1 to 2c3, detector 2d, and controller 2e. Detector 2d includes voltage detectors 2d1 to 2d3.

Bi-directional DCDC converter 2a is one example of the state setting means.

Bi-directional DCDC converter 2a selectively performs charging and discharging of a series battery unit for which SOC is set or calibrated (which will be referred to hereinbelow as “target battery unit for setting”), among series battery units 11 to 13. Bi-directional DCDC converter 2a is used to set the target battery unit for setting, into one of the predetermined states, either the fully charged state or fully discharged state (which will be simply referred to hereinbelow as “the predetermined state”).

Here, the target battery unit for setting is one example of the target storage battery unit for setting.

Switches 2b1 to 2b3 are one example of the plural first switches.

Switches 2b1 to 2b3 correspond to series battery units 11 to 13, respectively. For example, switch 2b1 corresponds to series battery unit 11, and switch 2b3 corresponds to series battery unit 13.

Switches 2b1 to 2b3 each are interposed between the corresponding series battery unit and bi-directional DCDC converter 2a.

Here, the number of the first switches (switches 2b1 to 2b3) is equal to the number of the series battery units.

Switches 2c1 to 2c3 are one example of the plural second switches.

Switches 2c1 to 2c3 correspond to series battery units 11 to 13, respectively. For example, switch 2c1 corresponds to series battery unit 11, and switch 2c3 corresponds to series battery unit 13.

Switches 2c1 to 2c3 each are interposed between the corresponding series battery unit and power line 2f.

Here, the number of the second switches (switches 2c1 to 2c3) is equal to the number of the series battery units.

Detector 2d detects each voltage of series battery units 11 to 13.

Voltage detectors 2d1 to 2d3 correspond to series battery units 11 to 13, respectively. For example, voltage detector 2d1 corresponds to series battery unit 11 and voltage detector 2d3 corresponds to series battery unit 13.

Voltage detectors 2d1 to 2d3 detect the voltage of the corresponding series battery units, respectively.

Controller 2e is one example of the control means.

Controller 2e holds each SOC of series battery units 11 to 13 in the internal database (not shown).

Controller 2e selects a target battery unit for setting, from series battery units 11 to 13.

Controller 2e, for example, periodically selects one target battery unit for setting, in turn, from series battery units 11 to 13.

Controller 2e turns on the switch corresponding to the target battery unit for setting (which will be referred to hereinbelow as “the control switch”) among switches 2b1 to 2b3, and turns off the switches other than the control switch, among switches 2b1 to 2b3.

Controller 2e turns off the switch corresponding to the target battery unit for setting (which will be referred to hereinbelow as “the corresponding switch”) among switches 2c1 to 2c3, and turns on the switches other than the corresponding switch, among switches 2c1 to 2c3.

Controller 2e turns on the control switch among switches 2b1 to 2b3 and turns off the switches other than the control switch, and turns off the corresponding switch and turns on the switches other than the corresponding switch among switches 2c1 to 2c3, then causes bi-directional DCDC converter 2a to set the target battery unit for setting into the predetermined state (fully charged state or fully discharged state).

When bi-directional DCDC converter 2a has set the target battery unit for setting into the predetermined state, controller 2e determines the SOC of the target battery unit for setting to be the value corresponding to the predetermined state.

For example, when the predetermined state is the fully charged state, controller 2e determines the SOC of the target battery unit for setting to be 100% at the time of the fully charged state. When the predetermined state is the fully discharged state, the controller 2e determines the SOC of the target battery unit for setting to be 0% at the time of the fully discharged state. Controller 2e modifies the SOC of the target battery unit for setting, held in the internal database, to the determined result of the SOC of the target battery unit for setting.

Power line 2f is connected to, for example a power system (not shown) that uses battery assembly device 100. The power system (not shown) using battery assembly device 100 controls charging and discharging of series battery units 11 to 13 using power line 2f.

Next, the operation will be described.

FIG. 2 is a flow chart for illustrating the operation of setting device 20.

Here, it is assumed that at the start of operation switches 2b1 to 2b3 are turned off and switches 2c1 to 2c3 are turned on. It is also assumed that the predetermined state is the fully charged state.

Controller 2e selects one target battery unit for setting from series battery units 11 to 13 at predetermined timing (e.g., at 2 a.m. on every Monday, or at 3 a.m. on the first of every month) (Step S201). The predetermined timing should not be limited to the above, but can be changed as appropriate.

Subsequently, controller 2e turns off the switch (the corresponding switch) corresponding to the target battery unit for setting, among switches 2c1 to 2c3, and turns on the switches other than the corresponding switch among switches 2c1 to 2c3 (Step S202).

When, of switches 2c1 to 2c3, the corresponding switch is turned off while the switches other than the corresponding switch are turned on, the target battery unit for setting among series battery units 11 to 13 is separated from power line 2f.

Since switches 2c1 to 2c3 have been turned on before Step S202, the switches other than the corresponding switch among switches 2c1 to 2c3 continue to be in the turned on state.

Then, controller 2e turns on the switch (control switch) corresponding to the target battery unit for setting, among switches 2b1 to 2b3, and turns off the switches other than the control switch among switches 2b1 to 2b3 (Step S203).

When, of switches 2b1 to 2b3, the control switch is turned on while the switches other than the control switch are turned off, the target battery unit for setting among series battery units 11 to 13 is connected to bi-directional DCDC converter 2a.

Since switches 2b1 to 2b3 have been turned off before Step S203, the switches other than the control switch among switches 2b1 to 2b3 continue to be in the off state.

Next, controller 2e causes bi-directional DCDC converter 2a to operate so as to charge the target battery unit for setting (Step S204).

FIG. 3 is a diagram for illustrating the on/off states of switches 2b1 to 2b3 and switches 2c1 to 2c3 when series battery unit 11 is the target battery unit for setting.

In FIG. 3, switch 2b1 corresponding to series battery unit 11 is turned on, switches 2b2 and 2b3 are turned off, switch 2c1 corresponding to series battery unit 11 is turned off, and switches 2c2 and 2c3 are turned on. As a result, bi-directional DCDC converter 2a performs charging of series battery unit 11.

Then, controller 2e, referring to the result of detection from the voltage detector corresponding to the target battery unit for setting (which will be referred to hereinbelow as “the corresponding voltage detector”) among voltage detectors 2d1 to 2d3, determines whether the voltage of the target battery unit for setting has reached the upper limit that corresponds to the fully charged state, that is, whether the target battery unit for setting has been fully charged (Step S205). Here, the upper limit has been previously stored in controller 2e.

When the voltage of the target battery unit for setting has not reached the upper limit, that is, when the target battery unit for setting has not been fully charged (Step S205), controller 2e returns the operation to Step S204.

On the other hand, when the voltage of the target battery unit for setting has reached the upper limit, that is, when the target battery unit for setting has been fully charged (Step S205), controller 2e determines the SOC of the target battery unit for setting to be 100%, and holds the determined result in the internal database (Step S206).

Subsequently, controller 2e, while maintaining the off/off state of each switch, causes bi-directional DCDC converter 2a to discharge the target battery unit for setting (Step S207).

Then, controller 2e, referring to the result of detection from voltage detectors 2d1 to 2d3, determines whether the voltage of the target battery unit for setting has become equal to the voltage of the other series battery units (Step S208).

If the voltage of the target battery unit for setting has not yet become equal to the voltage of the other series battery units (Step S208), controller 2e returns the operation to Step S207.

On the other hand, when the voltage of the target battery unit for setting has become equal to the voltage of the other series battery units (Step S208), controller 2e determines whether controller 2e has selected all of series battery units 11 to 13 as the target battery units for setting after the predetermined timing (Step S209).

If controller 2e has not yet selected all of series battery units 11 to 13 as the target battery unit for setting (Step S209), controller 2e selects another target battery unit for setting, from the series battery units that have not bee selected as the target battery unit (Step S210) and returns the operation to Step S202.

On the other hand, only when controller 2e has selected all of series battery units 11 to 13 as the target battery unit for setting (Step S209), controller 2e ends the SOC setting process of the target battery unit for setting.

Here, when the fully discharged state is used as the predetermined state, controller 2e causes bi-directional DCDC converter 2a to operate so that the target battery unit for setting is discharged at Step S204, determines whether the voltage of the target battery unit for setting has reached the lower limit that corresponds to the fully discharged state at Step S205, and sets the SOC of the target battery unit to be 0% when the voltage of the target battery unit for setting has reached the lower limit at Step S206. Here, the lower limit has been previously stored in controller 2e.

Next, the effect of the present exemplary embodiment will be described.

According to the present exemplary embodiment, bi-directional DCDC converter 2a sets the series battery unit at one of the predetermined states, either the fully charged state or the fully discharged state. Switches 2b1 to 2b3 are made to correspond to series battery units 11 to 13, respectively, and each is interposed between the corresponding series battery unit and bi-directional DCDC converter 2a.

Switches 2c1 to 2c3 are made to correspond to series battery units 11 to 13, respectively, and each is interposed between the corresponding series battery unit and power line 2f.

Controller 2e turns on the control switch corresponding to the target battery unit for setting among switches 2b1 to 2b3, turns on the switches other than the corresponding switch corresponding to the target battery unit for setting among switches 2c1 to 2c3, so as to cause bi-directional DCDC converter 2a to set the target battery unit for setting into the predetermined state, then determines the SOC of the target battery unit for setting to be the value corresponding into the predetermined state.

It is therefore possible to set the SOC of the target battery unit for setting to be the value corresponding to the predetermined state while connecting the series battery units other than the target battery unit for setting among series battery units 11 to 13 to power line 2f and while keeping the target battery unit for setting, at the predetermined state (fully charged state or fully discharged state).

As a result, even if power line 2f is connected to a power system in which the series battery units 11 to 13 are repeatedly charged and discharged without being fully charged or fully discharged, it is possible to correct the error of the SOC of the target battery unit for setting.

The above effect can also be obtained in setting device 20 formed of bi-directional DCDC converter 2a, switches 2b1 to 2b3, switches 2c1 to 2c3 and controller 2e.

FIG. 4 is a diagram showing setting device 20 formed of bi-directional DCDC converter 2a, switches 2b1 to 2b3 and switches 2c1 to 2c3, and controller 2e.

Also in this exemplary embodiment, controller 2e determines the SOC of the target battery unit for setting to be 100% at the time of the fully charged state when the predetermined state is the fully charged state and determines the SOC of the target battery unit for setting to be 0% at the time of the fully discharged state when the predetermined state is the fully discharged state.

Accordingly, it is possible to correctly calibrate the SOC of the target battery unit for setting.

In the exemplary embodiments described heretofore, the illustrated configurations are mere examples, so that the present invention should not be limited to the configurations.

Although the present invention has been explained with reference to the exemplary embodiments, the present invention should not be limited to the above exemplary embodiments. Various modifications that can be understood by those skilled in the art may be made to the structures and details of the present invention within the scope of the present invention. This application claims priority based on Japanese Patent Application No. 2012-65445, filed on Mar. 22, 2012, and should incorporate all the disclosures thereof herein.

### BRIEF DESCRIPTION OF THE DRAWINGS

100 battery assembly device

11-13 series battery unit

20 setting device

2a bi-directional DCDC converter

2b1 to 2b3, 2c1 to 2c3, switch

2d detector 2d1 to 2d3 voltage detector

2e controller

1. A setting device for determining the SOC of a target storage battery unit for setting among a plurality of storage battery units for which charging and discharging is performed using a power line, comprising:
a state setting means that sets the storage battery unit into one of two predetermined states, a the fully charged state or a fully discharged state;
a plurality of first switches, corresponding to the plural storage battery units respectively, and each interposed between the corresponding storage battery unit and the state setting means;
a plurality of second switches, corresponding to the plural storage battery units respectively, and each interposed between the corresponding storage battery unit and the power line; and,
a control means that turns on the first switch, among the plural first switches, corresponding to the target storage battery unit to be set into a predetermined state, turns on the second switches among the plural second switches, other than the second switch, corresponding to the target storage battery unit to be set into a predetermined state, and determines the SOC of the target storage battery unit that is to be set to the value corresponding to the predetermined state when the state setting means sets the target storage battery unit that is to be set into the predetermined state.

2. The setting device according to claim 1, wherein when the predetermined state is the fully charged state, the control means sets the value corresponding to the predetermined state to 100%, whereas when the predetermined state is the fully discharged state, the control means sets the value corresponding to the predetermined state to 0%.

3. The setting device according to claim 1, wherein the state setting means is a bi-directional DCDC converter.

4. A battery assembly device comprising a plurality of storage battery units and a setting device according to claim 1.

5. A setting method for use in a setting device for determining the SOC of a target storage battery unit for setting among a plurality of storage battery units for which charging and discharging is performed using a power line, the setting device including a state setting means for setting the storage battery unit to one of two predetermined states, either the fully charged state or the fully discharged state, comprising the steps of:
turning on the first switch corresponding to the target storage battery unit for setting among the plural first switches that respectively correspond to the plural storage battery units and that are each interposed between the corresponding storage battery unit and the state setting means;
turning on the second switches other than the second switch corresponding to the target storage battery unit for setting among the plural second switches that respectively correspond to the plural storage battery units and that are each interposed between the corresponding storage battery unit and the power line; and,
determining the SOC of the target storage battery unit for setting to be the value corresponding to the predetermined state when the state setting means sets the target storage battery unit for setting the storage battery unit into the predetermined state.
